(19) United States
(12) Patent Application Publication
(10) Pub. No.: US 2026/0291464 A1
(43) Pub. Date: Sep. 24, 2026

(54) Acoustic Devices

(71) Applicant: Sonocharge Energy, Inc, Mountain View, CA (US)

(72) Inventors: William CONNACHER, Mountain View, CA (US); An HUANG, Mountain View, CA (US); Haodong LIU, Mountain View, CA (US); Shuai ZHANG, Mountain View, CA (US)

(21) Appl. No.: 19/672,949

(22) Filed: May 11, 2026

Related U.S. Application Data
(63) Continuation of application No. PCT/US2024/055158, filed on Nov. 8, 2024.
(60) Provisional application No. 63/597,617, filed on Nov. 9, 2023.

(51) Int. Cl. H03H 9/25; H03H 9/02

(52) U.S. Cl. CPC H03H 9/25; H03H 9/02228; H03H 9/02559; H03H 9/02992

(57) ABSTRACT

In one aspect, the present disclosure provides an acoustic device configured to be used with an energy device. The acoustic device may comprise a transducer configured to generate and transmit acoustic waves into the energy device. The transducer may be based on one or more physical or geometric design parameters that are configured to (1) optimize mass transportation within the energy device, and (2) match or accommodate one or more size or form factor constraints associated with the energy device.

### CROSS REFERENCE

This application is a continuation of PCT/US2024/055158, filed 2024 Nov. 8, which claims the benefit of U.S. Provisional Application No. 63/597,617, filed 2023 Nov. 9, both of which are entirely incorporated herein by reference.

### BACKGROUND

The surge in global demand for energy over the last decades has spurred a concurrent demand for high-capacity and long-lasting energy devices to meet present and future global energy demand. Acoustic waves delivered to an electrolyte of an energy device can enhance the performance of the energy device. The size or magnitude of the effect of an acoustic device on the energy device can depend in part on the design of the acoustic device or acoustic wave transducer. Current acoustic devices have transducer designs that may not be customized or optimized for various energy device types and form factors. There is a need to configure acoustic transducer designs to enhance and optimize the performance of the energy device.

### SUMMARY

In an aspect, the present disclosure provides an acoustic device configured to be used with an energy device, the acoustic device comprising: a transducer configured to generate and transmit acoustic waves into the energy device, wherein the transducer is based on one or more physical or geometric design parameters that are configured to (1) optimize mass transportation within the energy device, and (2) match or accommodate one or more size or form factor constraints associated with the energy device.

In some embodiments of any one of the acoustic devices disclosed herein, one or more physical or geometric design parameters are further configured to (3) optimize one or more performance metrics for the energy device, wherein the one or more performance metrics comprises a quality (Q) factor, impedance matching, or losses/attenuation. In some embodiments of any one of the acoustic devices disclosed herein, the acoustic waves comprise at least one of the following: surface acoustic waves (SAW), Lamb waves, flexural waves, thickness mode vibrations, mixed-mode waves, longitudinal waves, shear mode vibrations, bulk wave vibrations, or any combination(s) thereof.

In some embodiments of any one of the acoustic devices disclosed herein, one or more physical or geometric design parameters are selected from a set of physical or geometric design parameters, wherein the set of physical or geometric design parameters is unique to a type of transducer. In some embodiments of any one of the acoustic devices disclosed herein, one or more physical or geometric design parameters are selected from the set of physical or geometric design parameters based on the effect of each design parameter on (1) and (2). In some embodiments of any one of the acoustic devices disclosed herein, one or more physical or geometric design parameters are selected from the set of physical or geometric design parameters based on the effects of different combinations of design parameters on (1) and (2).

In some embodiments of any one of the acoustic devices disclosed herein, the type of transducer is selected from the group consisting of interdigital transducer, thickness mode transducer, and lamb wave transducer. In some embodiments of any one of the acoustic devices disclosed herein, the transducer comprises an interdigital transducer. In some embodiments of any one of the acoustic devices disclosed herein, the interdigital transducer comprises a straight finger interdigital transducer (SIDT). In some embodiments of any one of the acoustic devices disclosed herein, the one or more physical or geometric design parameters for the SIDT comprise one or more of the following: number of finger pairs (N_{fp}), finger width (F_{w}), spacing between fingers (Fₛ), aperture (A), number of reflectors (Nᵣ), reflector width (R_{w}), spacing between reflectors (Rₛ), space between last finger and first reflector (FRₛ), width of electrode busbar (B), length of electrode busbar (L), length of electrode busbar extension to the left (Lₑₓₜ₁), length of electrode busbar extension to the right (Lₑₓₜ₂), finger to busbar separation (FBₛ), or busbar to finger extension (Bₑₓₜ). In some embodiments of any one of the acoustic devices disclosed herein, N_{fp} is about 5 to about 50, F_{w} is about 5 micrometers (μm) to about 100 μm, Fₛ is about 5 μm to about 100 μm, A is about 2 millimeters (mm) to about 20 mm, Nᵣ is about 0 to about 50, R_{w} is about 5 μm to about 100 μm, FRₛ is about 5 μm to about 300 μm, or B is about 0.5 mm to about 50 mm.

In some embodiments of any one of the acoustic devices disclosed herein, one or more physical or geometric design parameters for the SIDT comprise rounded corners of the IDT structures to avoid local electric field intensification. In some embodiments of any one of the acoustic devices disclosed herein, the interdigital transducer comprises a focused interdigital transducer (FIDT). In some embodiments of any one of the acoustic devices disclosed herein, the one or more physical or geometric design parameters for the FIDT comprise one or more of the following: number of finger pairs (N_{fp}), finger width (F_{w}), spacing between fingers (Fₛ), focal angle (D), focal length (Lf), number of reflectors (Nᵣ), reflector width (R_{w}), spacing between reflectors (Rₛ), space between last finger and first reflector (FRₛ), width of electrode busbar (B), or length of electrode busbar (L). In some embodiments of any one of the acoustic devices disclosed herein, N_{fp} is about 5 to about 50, F_{w} is about 5 μm to about 100 μm, Fₛ is about 5 μm to about 100 μm, D is about 30 degrees to about 90 degrees, L_{f} is about 2 mm to about 20 mm, Nᵣ is about 0 to about 50, R_{w} is about 5 μm to about 100 μm, Rₛ is about 5 μm to about 100 μm, FRₛ is about 5 μm to about 300 μm, B is about 0.5 mm to about 50 mm, or L is about 0.5 mm to about 50 mm.

In some embodiments of any one of the acoustic devices disclosed herein, the FIDT is a circular arc FIDT (FIDT-C). In some embodiments of any one of the acoustic devices disclosed herein, the FIDT-C comprises a plurality of fingers in a shape of concentric circles. In some embodiments of any one of the acoustic devices disclosed herein, the FIDT is an FIDT-W comprising a plurality of fingers in the shape of a slowness curve of a substrate on which the FIDT-W is fabricated.

In some embodiments of any one of the acoustic devices disclosed herein, the transducer comprises a thickness mode transducer (TMT). In some embodiments of any one of the acoustic devices disclosed herein, the TMT has a rectangular shape. In some embodiments of any one of the acoustic devices disclosed herein, one or more physical or geometric design parameters for the rectangular-shaped TMT comprise a length (L), a width (W), and a thickness (T). In some embodiments of any one of the acoustic devices disclosed herein, L is about 1 mm to about 50 mm, W is about 1 mm to about 50 mm, and T is about 0.2 mm to about 2 mm. In some embodiments of any one of the acoustic devices disclosed herein, the TMT has an elliptical shape. In some embodiments of any one of the acoustic devices disclosed herein, the one or more physical or geometric design parameters for the elliptical-shaped TMT comprise a first radius (R₁), a second radius (R₂), and a thickness (T). In some embodiments of any one of the acoustic devices disclosed herein, R₁ is about 0.5 mm to about 25 mm, R₂ is about 0.5 mm to about 25 mm, and T is about 0.2 mm to about 2 mm.

In some embodiments of any one of the acoustic devices disclosed herein, the transducer comprises a lamb wave transducer (LWT). In some embodiments of any one of the acoustic devices disclosed herein, the one or more physical or geometric design parameters for the LWT comprise one or more of the following: number of finger pairs (N_{fp}), finger width (F_{w}), spacing between fingers (Fₛ), aperture width (A), number of reflectors (Nᵣ), reflector width (R_{w}), spacing between reflectors (Rₛ), space between last finger and first reflector (FRₛ), width of electrode busbar (B), length of electrode busbar (L), length of electrode busbar extension to the left (Lₑₓₜ₁), or length of electrode busbar extension to the right (Lₑₓₜ₂). In some embodiments of any one of the acoustic devices disclosed herein, N_{fp} is about 5 to about 50, F_{w} is about 5 μm to about 100 μm, Fₛ is about 5 μm to about 100 μm, A is about 2 mm to about 20 mm, Nᵣ is about 0 to about 50, R_{w} is about 5 μm to about 100 μm, Rₛ is about 5 μm to about 100 μm, FRₛ is about 5 μm to about 300 μm, or B is about 0.5 mm to about 50 mm.

In some embodiments of any one of the acoustic devices disclosed herein, the transducer is configured to isolate the acoustic waves to a surface of the energy device and occupy minimal lateral space on the energy device. In some embodiments of any one of the acoustic devices disclosed herein, the transducer is configured to isolate the acoustic waves to a surface of the energy device and increase maximum vibrational amplitude for a given voltage signal. In some embodiments of any one of the acoustic devices disclosed herein, the transducer is configured to generate a large vibrational amplitude at a relatively low frequency and occupy minimal lateral space on the energy device.

In an aspect, the present disclosure provides a system comprising the acoustic device and the energy device as disclosed herein. In some embodiments of any one of the systems disclosed herein, the energy device comprises an electrochemical cell. In some embodiments of any one of the systems disclosed herein, the electrochemical cell is configured to be used in a solid-state battery, a fuel cell, an electrolyzer, or a flow battery.

### INCORPORATION BY REFERENCE

All publications, patents, and patent applications mentioned in this specification are herein incorporated by reference to the same extent as if each individual publication, patent, or patent application was specifically and individually indicated to be incorporated by reference.

### BRIEF DESCRIPTION OF THE DRAWINGS

The novel features of the disclosure are set forth with particularity in the appended claims. A better understanding of the features and advantages of the present disclosure will be obtained by reference to the following detailed description that sets forth illustrative embodiments, in which the principles of the disclosure are utilized, and the accompanying drawings, of which:

FIG. 1A depicts schematically an exemplary straight finger interdigital transducer (SIDT), according to some embodiments of the disclosure;

FIG. 1B depicts schematically a side view of an exemplary straight finger interdigital transducer (SIDT) deposited on a substrate, according to some embodiments of the disclosure;

FIG. 2A depicts schematically an exemplary circular arc focused interdigital transducer (FIDT-C), according to some embodiments of the disclosure;

FIG. 2B depicts schematically an exemplary FIDT-C with reflectors, according to some embodiments of the disclosure;

FIG. 2C depicts an example FIDT with fingers in the shape of a slowness curve of the substrate (FIDT-W), according to some embodiments of the disclosure;

FIG. 3A depicts an exemplary rectangular thickness mode transducer (TMT), according to some embodiments of the disclosure;

FIG. 3B depicts an exemplary elliptical TMT, according to some embodiments of the disclosure;

FIG. 3C depicts schematically a side view of an exemplary TMT deposited on a substrate, according to some embodiments of the disclosure;

FIG. 4 depicts schematically a side view of an exemplary lamb wave transducer (LWT) deposited on a substrate, according to some embodiments of the disclosure;

FIG. 5 shows a computer system in communication with the acoustic devices and/or energy devices, according to some embodiments of the disclosure;

FIG. 6 shows an example vibrational velocity (VV) spectrum, according to some embodiments of the disclosure;

FIG. 7 shows an example spatial map of the surface of an FIDT device near the focal spot, according to some embodiments of the disclosure;

FIG. 8A shows an acoustic device operably coupled to an energy device, according to some embodiments of the disclosure; and

FIGS. 8B-8E show exemplary configurations of an acoustic device coupled to an energy device, according to some embodiments of the disclosure.

### DETAILED DESCRIPTION

Provided herein are acoustic devices or acoustic modules that can improve the performance and lifetime of an energy device or an electrochemical device. The acoustic device can comprise one or more transducers. The one or more transducers are capable of generating and transmitting acoustic waves. The acoustic waves may efficiently facilitate mass transportation of mobile species, e.g., ions, and mitigate or modulate ion deposition and/or inhomogeneous distribution that may deleteriously impact the performance of the energy device or electrochemical device. The acoustic device provided herein can minimize the attenuation of the acoustic waves by other structures within the energy device or through other forms of dissipation.

In some embodiments, the present disclosure provides an acoustic device configured to be used with an energy device. The acoustic device may comprise a transducer configured to generate and transmit acoustic waves into the energy device. In some embodiments, the transducer may be based on one or more physical or geometric design parameters. In some embodiments, one or more physical or geometric design parameters may be configured to optimize mass transportation within the energy device. In some embodiments, one or more physical or geometric design parameters may be configured to match or accommodate one or more size or form factor constraints associated with the energy device.

The pattern or design of the transducer (and the acoustic device) is crucial in the improvement of the performance of the energy device. In some embodiments, the transducer can be designed to occupy minimal space, e.g., lateral space, on the energy device, increase maximum vibrational amplitude for a given voltage signal, and/or generate a large vibrational amplitude at a relatively low frequency.

In some embodiments, the transducer can be configured to isolate the acoustic waves to a surface of the energy device and occupy minimal lateral space on the energy device.

In some embodiments, the transducer can be configured to isolate the acoustic waves to a surface of the energy device and increase the maximum vibrational amplitude for a given voltage signal.

In some embodiments, the transducer can be configured to generate a large vibrational amplitude at a relatively low frequency and occupy minimal lateral space on the energy device.

In some embodiments, one or more physical or geometric design parameters of the transducer can be selected from a set of physical or geometric design parameters. In some embodiments, the set of physical or geometric design parameters may be unique to a type of transducer.

In some embodiments, one or more physical or geometric design parameters can be selected from the set of physical or geometric design parameters based on the effect of each design parameter on optimizing mass transportation within the energy device.

In some embodiments, one or more physical or geometric design parameters can be selected from the set of physical or geometric design parameters based on the effect of each design parameter on matching or accommodating one or more size or form factor constraints associated with the energy device.

For example, a longer cylindrical cell may require a lower frequency. In some cases, a straight finger interdigital transducer may use larger fingers and spacings. In some cases, a thickness mode transducer may be used.

In some cases, smaller cells with less spacing between the cells may require a smaller transducer to fit within the cells. This may require the number of finger pairs, the number of reflectors, or the aperture width to be reduced.

In some embodiments, the acoustic device can be disposed at various locations within and/or upon the interior of the energy device. The acoustic device may be integrated into an energy device having any form factor. In some embodiments, the energy device may be configured to adapt to the shape, contours, and/or surface features of its surroundings. The orientation, location, number, and/or operation frequency of the acoustic device may be adjusted in order to effectively agitate electrolyte over the energy device and/or electrodes, regardless of the form factor of the energy device.

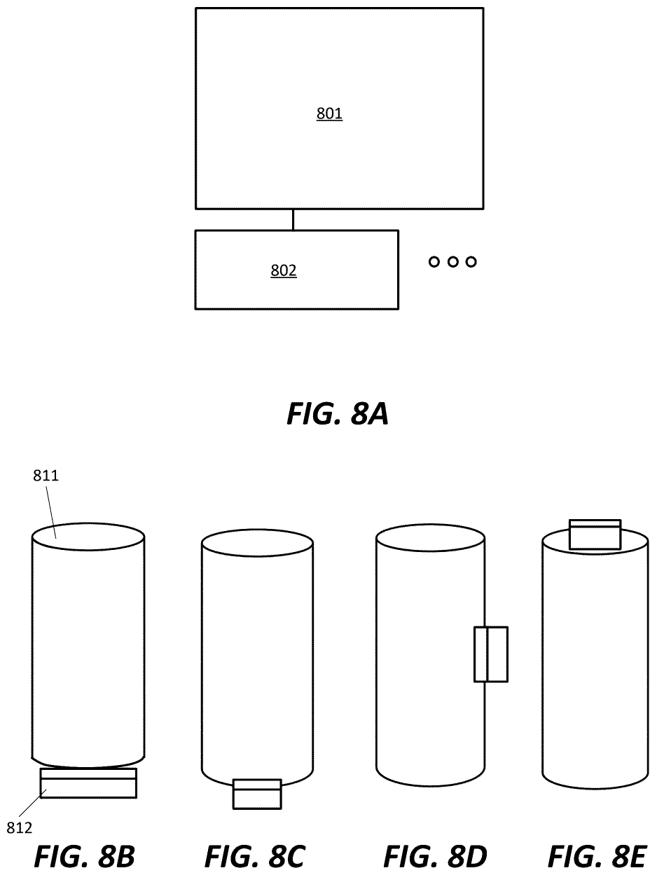

In some embodiments, the acoustic device can be disposed at an exterior (e.g., a surface) of the energy device. The acoustic device disposed at the exterior of the energy device has more flexibility in the design of the acoustic device in terms of the size, shape, contours, and/or surface features. The acoustic device can be disposed at various locations at an exterior (e.g., a surface) of the energy device. FIG. 8A shows an acoustic device 802 operably coupled to an energy device 801. FIGS. 8B-8E show exemplary configurations of acoustic device 812 coupled to an energy device 811 where the acoustic device is at different locations at the external surface of the energy device, e.g., a cylindrical energy device, for example, at the bottom surface (FIGS. 8B and 8C), at the side surface (FIG. 8D), or at the top surface (FIG. 8E). The acoustic device can cover a big portion of the surface, e.g., FIG. 8B, or a small portion of the surface, e.g., FIG. 8C.

In some embodiments, based on the size or form factor constraints of the energy device, the design of the transducer and the acoustic device can be optimized accordingly. For example, the transducer and the acoustic device can be configured to have a size or dimension that is substantially the same as the size or dimension of a cell of the energy device. In some embodiments, the transducer and the acoustic device can be configured to have a size or dimension that is at least about 5%, at least about 10%, at least about 15%, at least about 20%, at least about 25%, at least about 30%, or more, smaller than the size or dimension of a cell of the energy device. In some embodiments, the transducer and the acoustic device can be configured to have a size or dimension that is at most about 30%, at most about 25%, at most about 20%, at most about 15%, at most about 10%, at most about 5%, or less, smaller than the size or dimension of a cell of the energy device. In some embodiments, the transducer and the acoustic device are configured to conform to the form factor of the energy device.

In some embodiments, one or more physical or geometric design parameters may be selected from the set of physical or geometric design parameters based on the effect of each design parameter on both (1) optimizing mass transportation within the energy device and (2) matching or accommodating one or more size or form factor constraints associated with the energy device.

In some embodiments, one or more physical or geometric design parameters may be selected from the set of physical or geometric design parameters based on effects of different combinations of design parameters on (1) optimizing mass transportation within the energy device and (2) matching or accommodating one or more size or form factor constraints associated with the energy device.

In some embodiments, one or more physical or geometric design parameters may be selected from the set of physical or geometric design parameters based further on the effects of the design parameter on optimizing one or more performance metrics for the energy device. In some embodiments, the one or more performance metrics for the energy device may comprise a quality (Q) factor, impedance matching, or losses/attenuation. A quality factor characterizes the ratio of the energy stored to energy dissipated, e.g., through thermal dissipation, during the charging cycle or during the energy storage. Impedance matching minimizes signal reflection or maximizes power transfer, e.g., during the charging cycle. Losses/attenuation relate to the loss of power or energy, e.g., during the charging cycle or during the energy storage.

In some embodiments, the one or more physical or geometric design parameters may be selected from the set of physical or geometric design parameters based on an effect of each design parameter on (1) optimizing mass transportation within the energy device, (2) matching or accommodating one or more size or form factor constraints associated with the energy device, and (3) optimizing one or more performance metrics for the energy device.

In some embodiments, the transducer can comprise a conductive material. In some embodiments, the transducer can comprise titanium, aluminum, copper, chromium, gold, nickel, tungsten, or tin, or a combination thereof. For example, the transducer can comprise a combination of tungsten and titanium, e.g., 90% tungsten/10% titanium. In some embodiments, the transducer may comprise a combination of tungsten and titanium with a ratio from 9:1 to 1:9. In some embodiments, the transducer can be patterned onto a substrate to form an acoustic device for various applications. In some embodiments, the transducer can be selected from the group consisting of an interdigital transducer, a thickness mode transducer, and a lamb wave transducer. In some embodiments, the acoustic device can comprise one or more transducers. In some embodiments, the acoustic device can comprise one or more different types of transducers.

### Interdigital Transducer (IDT)

In some embodiments, the transducer comprises an interdigital transducer (IDT). In some embodiments, the IDT comprises a plurality of electrodes, e.g., metallic electrodes. In some embodiments, the IDT comprises two interlocking comb-shaped arrays of electrodes. IDT can convert electric signals to surface acoustic waves (SAW) by generating periodically distributed mechanical forces via the piezoelectric effect. In some embodiments, the plurality of electrodes can have various sizes, dimensions, orientations, and configurations.

### Straight Finger Interdigital Transducer (SIDT)

In some embodiments, the interdigital transducer comprises a straight finger interdigital transducer (SIDT). In some embodiments, an SIDT can isolate acoustic waves to one surface and allow the choice of frequency in a wide range by photolithography while occupying minimal lateral space. In some embodiments, the frequency can be from about 10 megahertz (MHz) to about 200 MHz. In some embodiments, the frequency can be at least about 10 MHz, at least about 20 MHz, at least about 50 MHz, at least about 100 MHz, at least about 150 MHz, or at least about 200 MHz. In some embodiments, the frequency can be at most about 200 MHz, at most about 150 MHz, at most about 100 MHz, at most about 50 MHz, at most about 20 MHz, or at most about 10 MHz.

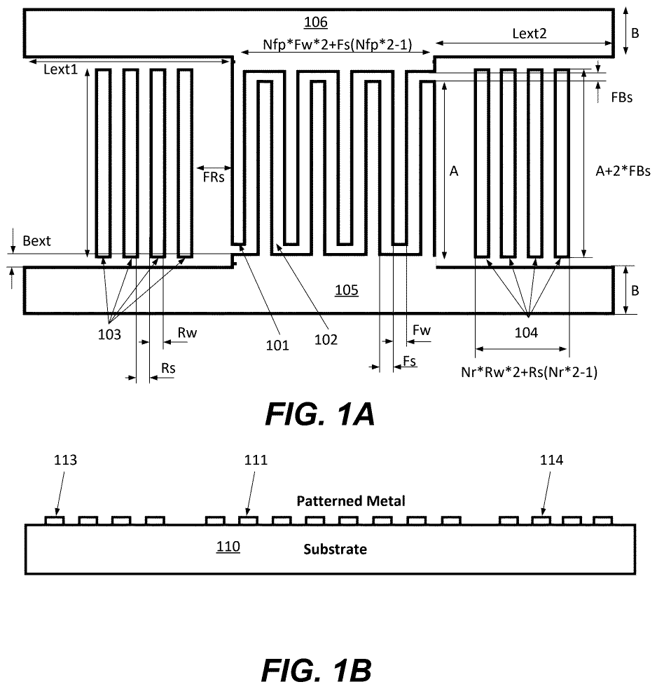

FIG. 1A depicts schematically an exemplary straight finger interdigital transducer (SIDT). The black region depicts the patterned metal on one side of a substrate. The SIDT may comprise a plurality of finger pairs (e.g., fingers 101 and 102 form a finger pair). The SIDT may comprise a plurality of reflectors (e.g., 103 and 104). The SIDT may comprise a pair of electrode busbars (e.g., 105 and 106). In some embodiments, the finger pairs may be substantially parallel to each other.

FIG. 1B depicts schematically a side view of an exemplary straight finger interdigital transducer (SIDT) deposited on a substrate 110. The SIDT may comprise a plurality of straight fingers, e.g., 111. The SIDT may comprise a plurality of reflectors, e.g., 113 and 114.

In some embodiments, the one or more physical or geometric design parameters for the SIDT comprise one or more of the following: number of finger pairs (N_{fp}), finger width (F_{w}), spacing between fingers (Fₛ), aperture (A), number of reflectors (Nᵣ), reflector width (R_{w}), spacing between reflectors (Rₛ), space between last finger and first reflector (FRₛ), width of electrode busbar (B), length of electrode busbar (L), length of electrode busbar extension to the left (Lₑₓₜ₁), length of electrode busbar extension to the right (Lₑₓₜ₂), finger to busbar separation (FBₛ), or busbar to finger extension (Bₑₓₜ).

In some embodiments, the length of electrode busbar L is defined by the formula: L=N_{fp}*F_{w}*2+Fₛ (N_{fp}*2−1). In some embodiments, the length of the reflector may be defined by the formula: Lr=A+2*FBs.

In some embodiments, the one or more physical or geometric design parameters for the SIDT comprise rounded corners of the IDT structures to avoid local electric field intensification.

In some embodiments, N_{fp} of an SIDT is from about 5 to about 10, from about 5 to about 20, from about 5 to about 30, from about 5 to about 40, from about 5 to about 50, from about 10 to about 20, from about 10 to about 30, from about 10 to about 40, from about 10 to about 50, from about 20 to about 30, from about 20 to about 40, from about 20 to about 50, from about 30 to about 40, from about 30 to about 50, or from about 40 to about 50.

In some embodiments, F_{w} of an SIDT is from about 5 micrometers (μm) to about 10 μm, from about 5 μm to about 20 μm, from about 5 μm to about 40 μm, from about 5 μm to about 60 μm, from about 5 μm to about 80 μm, from about 5 μm to about 100 μm, from about 10 μm to about 20 μm, from about 10 μm to about 40 μm, from about 10 μm to about 60 μm, from about 10 μm to about 80 μm, from about 10 μm to about 100 μm, from about 20 μm to about 40 μm, from about 20 μm to about 60 μm, from about 20 μm to about 80 μm, from about 20 μm to about 100 μm, from about 40 μm to about 60 μm, from about 40 μm to about 80 μm, from about 40 μm to about 100 μm, from about 60 μm to about 80 μm, from about 60 μm to about 100 μm, or from about 80 μm to about 100 μm.

In some embodiments, Fₛ of an SIDT is from about 5 μm to about 10 μm, from about 5 μm to about 20 μm, from about 5 μm to about 40 μm, from about 5 μm to about 60 μm, from about 5 μm to about 80 μm, from about 5 μm to about 100 μm, from about 10 μm to about 20 μm, from about 10 μm to about 40 μm, from about 10 μm to about 60 μm, from about 10 μm to about 80 μm, from about 10 μm to about 100 μm, from about 20 μm to about 40 μm, from about 20 μm to about 60 μm, from about 20 μm to about 80 μm, from about 20 μm to about 100 μm, from about 40 μm to about 60 μm, from about 40 μm to about 80 μm, from about 40 μm to about 100 μm, from about 60 μm to about 80 μm, from about 60 μm to about 100 μm, or from about 80 μm to about 100 μm.

In some embodiments, A is from about 2 millimeters (mm) to about 5 mm, from about 2 mm to about 10 mm, from about 2 mm to about 15 mm, from about 2 mm to about 20 mm, from about 5 mm to about 10 mm, from about 5 mm to about 15 mm, from about 5 mm to about 20 mm, from about 10 mm to about 15 mm, from about 10 mm to about 20 mm, or from about 15 mm to about 20 mm.

In some embodiments, Nᵣ is from 0 to about 5, from about 5 to about 10, from about 5 to about 20, from about 5 to about 30, from about 5 to about 40, from about 5 to about 50, from about 10 to about 20, from about 10 to about 30, from about 10 to about 40, from about 10 to about 50, from about 20 to about 30, from about 20 to about 40, from about 20 to about 50, from about 30 to about 40, from about 30 to about 50, or from about 40 to about 50. In some embodiments, the transducer does not comprise a reflector.

In some embodiments, R_{w} is from about 5 μm to about 10 μm, from about 5 μm to about 20 μm, from about 5 μm to about 40 μm, from about 5 μm to about 60 μm, from about 5 μm to about 80 μm, from about 5 μm to about 100 μm, from about 10 μm to about 20 μm, from about 10 μm to about 40 μm, from about 10 μm to about 60 μm, from about 10 μm to about 80 μm, from about 10 μm to about 100 μm, from about 20 μm to about 40 μm, from about 20 μm to about 60 μm, from about 20 μm to about 80 μm, from about 20 μm to about 100 μm, from about 40 μm to about 60 μm, from about 40 μm to about 80 μm, from about 40 μm to about 100 μm, from about 60 μm to about 80 μm, from about 60 μm to about 100 μm, or from about 80 μm to about 100 μm.

In some embodiments, Rₛ is from about 5 μm to about 10 μm, from about 5 μm to about 20 μm, from about 5 μm to about 40 μm, from about 5 μm to about 60 μm, from about 5 μm to about 80 μm, from about 5 μm to about 100 μm, from about 10 μm to about 20 μm, from about 10 μm to about 40 μm, from about 10 μm to about 60 μm, from about 10 μm to about 80 μm, from about 10 μm to about 100 μm, from about 20 μm to about 40 μm, from about 20 μm to about 60 μm, from about 20 μm to about 80 μm, from about 20 μm to about 100 μm, from about 40 μm to about 60 μm, from about 40 μm to about 80 μm, from about 40 μm to about 100 μm, from about 60 μm to about 80 μm, from about 60 μm to about 100 μm, or from about 80 μm to about 100 μm.

In some embodiments, FRₛ is from about 5 μm to about 10 μm, about 5 μm to about 20 μm, about 5 μm to about 50 μm, about 5 μm to about 100 μm, about 5 μm to about 200 μm, about 5 μm to about 300 μm, about 10 μm to about 20 μm, about 10 μm to about 50 μm, about 10 μm to about 100 μm, about 10 μm to about 200 μm, about 10 μm to about 300 μm, about 20 μm to about 50 μm, about 20 μm to about 100 μm, about 20 μm to about 200 μm, about 20 μm to about 300 μm, about 50 μm to about 100 μm, about 50 μm to about 200 μm, about 50 μm to about 300 μm, about 100 μm to about 200 μm, about 100 μm to about 300 μm, or about 200 μm to about 300 μm.

In some embodiments, B of an SIDT is from about 0.5 mm to about 1 mm, from about 0.5 mm to about 5 mm, from about 0.5 mm to about 10 mm, from about 0.5 mm to about 20 mm, from about 0.5 mm to about 30 mm, from about 0.5 mm to about 40 mm, from about 0.5 mm to about 50 mm, from about 5 mm to about 10 mm, from about 5 mm to about 20 mm, from about 5 mm to about 30 mm, from about 5 mm to about 40 mm, from about 5 mm to about 50 mm, from about 10 mm to about 20 mm, from about 10 mm to about 30 mm, from about 10 mm to about 40 mm, from about 10 mm to about 50 mm, from about 20 mm to about 30 mm, from about 20 mm to about 40 mm, from about 20 mm to about 50 mm, from about 30 mm to about 40 mm, from about 30 mm to about 50 mm, or from about 40 mm to about 50 mm.

In some embodiments, L is from about 50 μm to about 100 μm, from about 50 μm to about 200 μm, from about 50 μm to about 500 μm, from about 50 μm to about 1000 μm, from about 50 μm to about 5000 μm, from about 50 μm to about 10000 μm, from about 50 μm to about 20000 μm, from about 100 μm to about 200 μm, from about 100 μm to about 500 μm, from about 100 μm to about 1000 μm, from about 100 μm to about 5000 μm, from about 100 μm to about 10000 μm, from about 100 μm to about 20000 μm, from about 200 μm to about 500 μm, from about 200 μm to about 1000 μm, from about 200 μm to about 5000 μm, from about 200 μm to about 10000 μm, from about 200 μm to about 20000 μm, from about 500 μm to about 1000 μm, from about 500 μm to about 5000 μm, from about 500 μm to about 10000 μm, from about 500 μm to about 20000 μm, from about 1000 μm to about 5000 μm, from about 1000 μm to about 10000 μm, from about 1000 μm to about 20000 μm, from about 5000 μm to about 10000 μm, from about 5000 μm to about 20000 μm, or from about 10000 μm to about 20000 μm.

In some embodiments, Lₑₓₜ₁ and/or Lₑₓₜ₂ may be from about 50 μm to about 100 μm, from about 50 μm to about 200 μm, from about 50 μm to about 500 μm, from about 50 μm to about 1000 μm, from about 50 μm to about 5000 μm, from about 50 μm to about 10000 μm, from about 50 μm to about 20000 μm, from about 100 μm to about 200 μm, from about 100 μm to about 500 μm, from about 100 μm to about 1000 μm, from about 100 μm to about 5000 μm, from about 100 μm to about 10000 μm, from about 100 μm to about 20000 μm, from about 200 μm to about 500 μm, from about 200 μm to about 1000 μm, from about 200 μm to about 5000 μm, from about 200 μm to about 10000 μm, from about 200 μm to about 20000 μm, from about 500 μm to about 1000 μm, from about 500 μm to about 5000 μm, from about 500 μm to about 10000 μm, from about 500 μm to about 20000 μm, from about 1000 μm to about 5000 μm, from about 1000 μm to about 10000 μm, from about 1000 μm to about 20000 μm, from about 5000 μm to about 10000 μm, from about 5000 μm to about 20000 μm, or from about 10000 μm to about 20000 μm.

### Focused Interdigital Transducer (FIDT)

In some embodiments, the interdigital transducer comprises a focused interdigital transducer (FIDT). In some embodiments, the axis of the FIDTs can be parallel to the direction of propagation of sound or an acoustic wave in the substrate. In some embodiments, the axis of the FIDTs may not be parallel to the direction of propagation of sound or an acoustic wave in the substrate. In some embodiments, the axis of the FIDTs can be arranged at an angle to the direction of propagation of sound or acoustic wave in the substrate. In some embodiments, the angle can be from about 0 degrees (°) to about 90°.

In some embodiments, the FIDT can generate convergent wavepackets, resulting in significant amplitude magnification at the focus (or focal point).

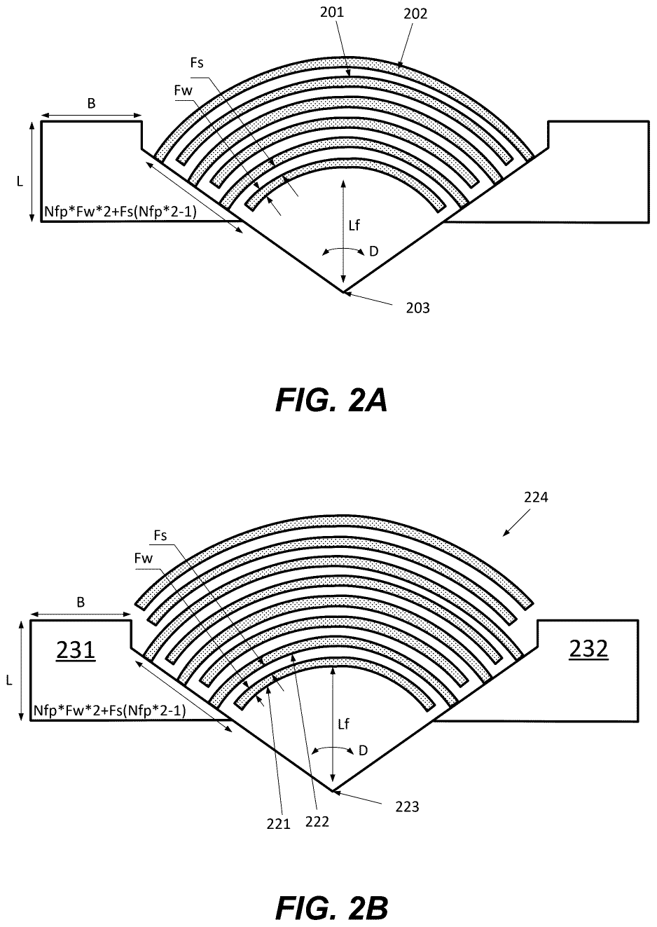

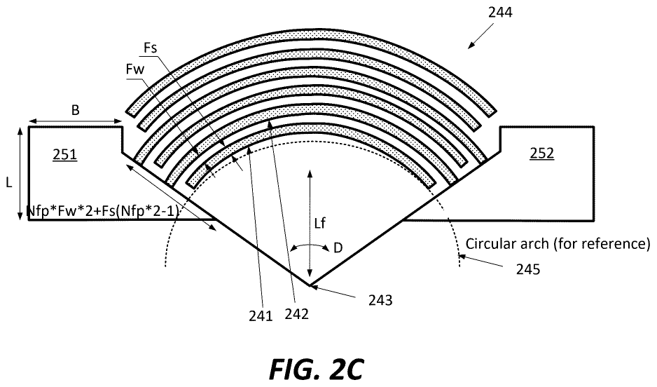

In some embodiments, the FIDT can be a circular arc FIDT (FIDT-C). FIG. 2A depicts schematically an exemplary circular arc focused interdigital transducer, e.g., an FIDT-C. The FIDT-C can comprise a plurality of finger pairs (e.g., 201 and 202 forming a finger pair) that are arranged in a focused configuration around a focal spot or focal point (or focus) 203 and a pair of electrode busbars (e.g., 210 and 211).

In some embodiments, an FIDT can comprise a plurality of reflectors. In some embodiments, the reflectors can be disposed on the side of the FIDT opposite the focal spot. FIG. 2B depicts schematically an exemplary FIDT-C with reflectors. The FIDT-C can comprise a plurality of finger pairs (e.g., 221 and 222 forming a finger pair) that are arranged in a focused configuration around a focal spot 223, a pair of electrode busbars (e.g., 231 and 232), and a plurality of reflectors 224 disposed at the side of the finger pairs opposite the focal spot 223.

In some embodiments, the substrate on which the FIDT is fabricated can be anisotropic. In some embodiments, the propagation directions of the acoustic waves can be altered by beam steering. The steered waves can converge to an elongated focal region that is displaced from the geometric center of the arc of the FIDT. In some embodiments, the effects of beam steering can be minimized by adjusting the curvature of the FIDT according to a slowness curve of the substrate. In some embodiments, the FIDT can comprise a plurality of fingers in the shape of a slowness curve of a substrate on which the FIDT is fabricated. This FIDT can be referred to as FIDT-W. FIG. 2C shows an example FIDT-W. The FIDT-W can comprise a plurality of finger pairs (e.g., 241 and 242 forming a finger pair) that are arranged in a focused configuration around a focal spot, a pair of electrode busbars (e.g., 251 and 252), and a plurality of reflectors 244 disposed at the side of the finger pairs opposite the focal spot 243. The curvature of the FIDT-W is adjusted according to the slowness curve of the substrate, and in FIG. 2C, the fingers are more curved in the center than at the edge. The dotted line 245 shows a circular arc as a comparison.

In some embodiments, the one or more physical or geometric design parameters for the FIDT (as shown in FIGS. 2A-2C) comprise one or more of the following: number of finger pairs (N_{fp}), finger width (F_{w}), spacing between fingers (Fₛ), focal angle (D), focal length (L_{f}), number of reflectors (Nᵣ), reflector width (R_{w}), spacing between reflectors (Rₛ), space between last finger and first reflector (FRₛ), width of electrode busbar (B), or length of electrode busbar (L). For FIDT-W, one or more physical or geometric design parameters can further comprise the curvature of the fingers or the slowness curve of the substrate. In some embodiments, the fingers may be more curved in the center than at the edge. In some embodiments, the fingers may have a curvature in the center that is at least about 1%, at least about 2%, at least about 5%, at least about 10%, at least about 15%, at least about 20%, at least about 30%, at least about 40%, or at least about 50% larger than the curvature at the edge. In some embodiments, the fingers may have a curvature in the center that is at most about 50%, at most about 40%, at most about 30%, at most about 20%, at most about 15%, at most about 10%, at most about 5%, at most about 2%, or at most about 1% larger than the curvature at the edge. In some embodiments, the fingers may be more curved at the edge than in the center. In some embodiments, the fingers may have a curvature at the edge that is at least about 1%, at least about 2%, at least about 5%, at least about 10%, at least about 15%, at least about 20%, at least about 30%, at least about 40%, or at least about 50% larger than the curvature in the center. In some embodiments, the fingers may have a curvature at the edge that is at most about 50%, at most about 40%, at most about 30%, at most about 20%, at most about 15%, at most about 10%, at most about 5%, at most about 2%, or at most about 1% larger than the curvature in the center.

In some embodiments, N_{fp} of an FIDT is from about 5 to about 10, from about 5 to about 20, from about 5 to about 30, from about 5 to about 40, from about 5 to about 50, from about 10 to about 20, from about 10 to about 30, from about 10 to about 40, from about 10 to about 50, from about 20 to about 30, from about 20 to about 40, from about 20 to about 50, from about 30 to about 40, from about 30 to about 50, or from about 40 to about 50.

In some embodiments, F_{w} of an FIDT is from about 5 micrometers (μm) to about 10 μm, from about 5 μm to about 20 μm, from about 5 μm to about 40 μm, from about 5 μm to about 60 μm, from about 5 μm to about 80 μm, from about 5 μm to about 100 μm, from about 10 μm to about 20 μm, from about 10 μm to about 40 μm, from about 10 μm to about 60 μm, from about 10 μm to about 80 μm, from about 10 μm to about 100 μm, from about 20 μm to about 40 μm, from about 20 μm to about 60 μm, from about 20 μm to about 80 μm, from about 20 μm to about 100 μm, from about 40 μm to about 60 μm, from about 40 μm to about 80 μm, from about 40 μm to about 100 μm, from about 60 μm to about 80 μm, from about 60 μm to about 100 μm, or from about 80 μm to about 100 μm.

In some embodiments, Fₛ of an FIDT is from about 5 μm to about 10 μm, from about 5 μm to about 20 μm, from about 5 μm to about 40 μm, from about 5 μm to about 60 μm, from about 5 μm to about 80 μm, from about 5 μm to about 100 μm, from about 10 μm to about 20 μm, from about 10 μm to about 40 μm, from about 10 μm to about 60 μm, from about 10 μm to about 80 μm, from about 10 μm to about 100 μm, from about 20 μm to about 40 μm, from about 20 μm to about 60 μm, from about 20 μm to about 80 μm, from about 20 μm to about 100 μm, from about 40 μm to about 60 μm, from about 40 μm to about 80 μm, from about 40 μm to about 100 μm, from about 60 μm to about 80 μm, from about 60 μm to about 100 μm, or from about 80 μm to about 100 μm.

In some embodiments, D of an FIDT is from about 30° to about 40°, from about 30° to about 50°, from about 30° to about 60°, from about 30° to about 70°, from about 30° to about 80°, from about 30° to about 90°, from about 30° to about 120°, from about 40° to about 50°, from about 40° to about 60°, from about 40° to about 70°, from about 40° to about 80°, from about 40° to about 90°, from about 40° to about 120°, from about 50° to about 60°, from about 50° to about 70°, from about 50° to about 80°, from about 50° to about 90°, from about 50° to about 120°, from about 60° to about 70°, from about 60° to about 80°, from about 60° to about 90°, from about 60° to about 120°, from about 70° to about 80°, from about 70° to about 90°, from about 70° to about 120°, from about 80° to about 90°, from about 80° to about 120°, or from about 90° to about 120°.

In some embodiments, L_{f} of an FIDT is from about 2 mm to about 5 mm, from about 2 mm to about 10 mm, from about 2 mm to about 15 mm, from about 2 mm to about 20 mm, from about 5 mm to about 10 mm, from about 5 mm to about 15 mm, from about 5 mm to about 20 mm, from about 10 mm to about 15 mm, from about 10 mm to about 20 mm, or from about 15 mm to about 20 mm.

In some embodiments, B of an FIDT is from about 0.5 mm to about 1 mm, from about 0.5 mm to about 5 mm, from about 0.5 mm to about 10 mm, from about 0.5 mm to about 20 mm, from about 0.5 mm to about 30 mm, from about 0.5 mm to about 40 mm, from about 0.5 mm to about 50 mm, from about 5 mm to about 10 mm, from about 5 mm to about 20 mm, from about 5 mm to about 30 mm, from about 5 mm to about 40 mm, from about 5 mm to about 50 mm, from about 10 mm to about 20 mm, from about 10 mm to about 30 mm, from about 10 mm to about 40 mm, from about 10 mm to about 50 mm, from about 20 mm to about 30 mm, from about 20 mm to about 40 mm, from about 20 mm to about 50 mm, from about 30 mm to about 40 mm, from about 30 mm to about 50 mm, or from about 40 mm to about 50 mm.

In some embodiments, L of an FIDT is from about 0.5 mm to about 1 mm, from about 0.5 mm to about 5 mm, from about 0.5 mm to about 10 mm, from about 0.5 mm to about 20 mm, from about 0.5 mm to about 30 mm, from about 0.5 mm to about 40 mm, from about 0.5 mm to about 50 mm, from about 5 mm to about 10 mm, from about 5 mm to about 20 mm, from about 5 mm to about 30 mm, from about 5 mm to about 40 mm, from about 5 mm to about 50 mm, from about 10 mm to about 20 mm, from about 10 mm to about 30 mm, from about 10 mm to about 40 mm, from about 10 mm to about 50 mm, from about 20 mm to about 30 mm, from about 20 mm to about 40 mm, from about 20 mm to about 50 mm, from about 30 mm to about 40 mm, from about 30 mm to about 50 mm, or from about 40 mm to about 50 mm.

### Thickness Mode Transducer (TMT)

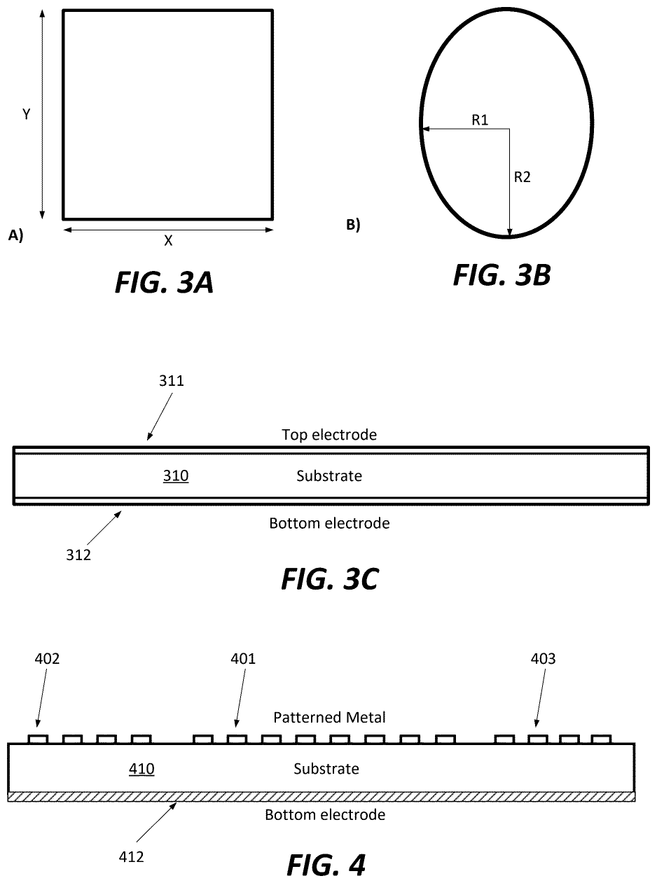

In some embodiments, the transducer comprises a thickness mode transducer (TMT). In some embodiments, the TMT has a rectangular shape. FIG. 3A depicts an exemplary rectangular-shaped TMT. In some embodiments, the one or more physical or geometric design parameters for the rectangular-shaped TMT comprise a length (L) in the x-axis, a width (W) in the y-axis, and a thickness (T).

In some embodiments, L and/or W of a TMT are from about 1 mm to about 5 mm, from about 1 mm to about 10 mm, from about 1 mm to about 20 mm, from about 1 mm to about 30 mm, from about 1 mm to about 40 mm, from about 1 mm to about 50 mm, from about 5 mm to about 10 mm, from about 5 mm to about 20 mm, from about 5 mm to about 30 mm, from about 5 mm to about 40 mm, from about 5 mm to about 50 mm, from about 10 mm to about 20 mm, from about 10 mm to about 30 mm, from about 10 mm to about 40 mm, from about 10 mm to about 50 mm, from about 20 mm to about 30 mm, from about 20 mm to about 40 mm, from about 20 mm to about 50 mm, from about 30 mm to about 40 mm, from about 30 mm to about 50 mm, or from about 40 mm to about 50 mm. In some embodiments, L and W may be the same (e.g., square TMT). In some embodiments, L and W may be different. In some embodiments, L may be smaller than W. In some embodiments, L may be larger than W.

In some embodiments, T of a rectangular TMT is from about 0.2 mm to about 0.5 mm, from about 0.2 mm to about 1 mm, from about 0.2 mm to about 1.5 mm, from about 0.2 mm to about 2 mm, from about 0.5 mm to about 1 mm, from about 0.5 mm to about 1.5 mm, from about 0.5 mm to about 2 mm, from about 1 mm to about 1.5 mm, from about 1 mm to about 2 mm, or from about 1.5 mm to about 2 mm.

In some embodiments, the TMT has an elliptical or oval shape. FIG. 3B depicts an exemplary elliptical TMT.

In some embodiments, the one or more physical or geometric design parameters for the elliptical TMT comprise a first radius (R₁), a second radius (R₂), and a thickness (T).

In some embodiments, R₁ and/or R₂ of a TMT are from about 0.5 mm to about 1 mm, from about 0.5 mm to about 5 mm, from about 0.5 mm to about 10 mm, from about 0.5 mm to about 20 mm, from about 0.5 mm to about 25 mm, from about 1 mm to about 5 mm, from about 1 mm to about 10 mm, from about 1 mm to about 20 mm, from about 1 mm to about 25 mm, from about 5 mm to about 10 mm, from about 5 mm to about 20 mm, from about 5 mm to about 25 mm, from about 10 mm to about 20 mm, from about 10 mm to about 25 mm, or from about 20 mm to about 25 mm.

In some embodiments, T of an elliptical TMT is from about 0.2 mm to about 0.5 mm, from about 0.2 mm to about 1 mm, from about 0.2 mm to about 1.5 mm, from about 0.2 mm to about 2 mm, from about 0.5 mm to about 1 mm, from about 0.5 mm to about 1.5 mm, from about 0.5 mm to about 2 mm, from about 1 mm to about 1.5 mm, from about 1 mm to about 2 mm, or from about 1.5 mm to about 2 mm.

In some embodiments, R₁ and R₂ can be the same (e.g., a circular TMT). In some embodiments, R₁ and R₂ can be different. In some embodiments, R₁ is larger than R₂. In some embodiments, R₁ is smaller than R₂.

FIG. 3C depicts schematically a side view of an exemplary TMT. The TMT 300 comprises a top electrode 311 and a bottom electrode 312 deposited onto the top surface and bottom surface of the substrate 310, respectively.

### Lamb Wave Transducer (LWT)

In some embodiments, the transducer comprises a lamb wave transducer (LWT). In some embodiments, the LWT can comprise a combined IDT, e.g., an SIDT or an FIDT, and a bottom electrode similar to that of a TMT. FIG. 4 depicts schematically a side view of an exemplary LMT deposited on a substrate 410. The LMT comprises a plurality of fingers, e.g., 401, and a plurality of reflectors, e.g., 402 and 403, deposited on a top surface of the substrate 410 and a bottom electrode 412 deposited on a bottom surface of the substrate 410.

In some embodiments, the one or more physical or geometric design parameters for the LWT comprise one or more of the following: number of finger pairs (N_{fp}), finger width (F_{w}), spacing between fingers (Fₛ), aperture width (A), number of reflectors (Nᵣ), reflector width (R_{w}), spacing between reflectors (Rₛ), space between last finger and first reflector (FRₛ), width of electrode busbar (B), length of electrode busbar (L), length of electrode busbar extension to the left (Lₑₓₜ₁), or length of electrode busbar extension to the right (Lₑₓₜ₂).

In some embodiments, one or more physical or geometric design parameters for the IDT part of the LWT can be any physical or geometric design parameter of the IDT provided herein.

In some embodiments, one or more physical or geometric design parameters for the TMT part of the LWT can be any physical or geometric design parameter of the TMT provided herein.

In some embodiments, the LMT can be any combination of an IDT and TMT disclosed herein.

### Substrate

In some embodiments, the transducer can be deposited on a substrate. In some embodiments, the substrate can comprise at least a piezoelectric material. In some embodiments, the piezoelectric material can comprise lithium niobate (LiNbO₃), lithium titanate (Li₂TiO₃), barium titanate (BaTiO₃), lead zirconate titanate (Pb(ZrxTi₁₋ₓ)O₃ wherein (0≤x≤1)), quartz, zinc oxide, aluminum nitride (AlN), langasite, lead magnesium niobate-lead titanate (PMN-PT), lead-free potassium sodium niobate (K_{0.5}Na_{0.5}NbO₃ or KNN), a doped derivative of lead-free potassium sodium niobate, polyvinylidene fluoride (PVDF), or a combination thereof.

In some embodiments, the substrate is a 128-degree Y-rotated, X-propagating lithium niobate single crystal. In some embodiments, the substrate is a 41-degree lithium niobate single crystal. In some embodiments, the lithium niobate single crystal is chemically reduced (e.g., black lithium niobate). In some embodiments, the substrate is zinc oxide. In some embodiments, the zinc oxide is deposited on a secondary substrate, e.g., silicon or polyamide. In some embodiments, the substrate is aluminum nitride. In some embodiments, the aluminum nitride is deposited on a secondary substrate, e.g., silicon or polyamide. In some embodiments, the substrate is PMN-PT. In some embodiments, the substrate is a dual substrate. In some embodiments, the substrate is a lithium niobate single crystal grown on a carrier, e.g., sapphire.

In some embodiments, the substrate can have a thickness from about 250 micrometers (μm) to about 500 μm, from about 250 μm to about 750 μm, from about 250 μm to about 1000 μm, from about 500 μm to about 750 μm, from about 500 μm to about 1000 μm, or from about 750 μm to about 1000 μm.

In some embodiments, the substrate can have a shape of a square, rectangle, triangle, or oval.

In some embodiments, the substrate can have a dimension from about 3 millimeters (mm) to about 5 mm, from about 3 mm to about 10 mm, from about 3 mm to about 15 mm, from about 3 mm to about 20 mm, from about 3 mm to about 25 mm, from about 5 mm to about 10 mm, from about 5 mm to about 15 mm, from about 5 mm to about 20 mm, from about 5 mm to about 25 mm, from about 10 mm to about 15 mm, from about 10 mm to about 20 mm, from about 10 mm to about 25 mm, from about 15 mm to about 20 mm, from about 15 mm to about 25 mm, or from about 15 mm to about 25 mm.

### Energy Device

In some embodiments, the energy device disclosed herein can be any energy-generating or energy-storing device.

In some embodiments, the energy device can comprise an electrochemical cell. In some embodiments, the electrochemical cell can be used in a solid-state or semi-solid-state battery, a fuel cell, an electrolyzer, a flow battery, or a metal-air battery. In some embodiments, the energy device can be regularly shaped or irregularly shaped. In some embodiments, the energy device can comprise at least one, at least two, at least three, at least four, at least five, at least six, at least seven, at least eight, at least nine, at least ten, at least 20, at least 30, at least 40, at least 50, at least 60, at least 70, at least 80, at least 90, at least 100, or more electrochemical cells. In some embodiments, the electrochemical cells can comprise cylindrical, prismatic, or pouch cells.

The acoustic devices can be integrated into individual energy devices. In some embodiments, the individual energy devices can, in turn, be integrated into energy systems. The format of the energy cells can be cylindrical, pouch, prismatic, or irregular. In some cases, the acoustic devices can also be integrated into energy systems, such as batteries, which comprise a plurality of cells. For example, the acoustic device can be mounted onto a battery such that it provides acoustic waves to the plurality of battery cells within the battery. In some instances, the individual cells can be grouped together to form a pouch (e.g., a cell pouch or prismatic pouch), wherein the individual cells may be individually equipped with an acoustic device. The cells within the pouches can be any battery cell, electrochemical cell, fuel cell (e.g., a solid oxide fuel cell (SOFC) or molten carbonate fuel cell (MCFC)), capacitor, or supercapacitor.

In some embodiments, the energy device can comprise at least two electrodes. In some embodiments, the energy device can comprise a cathode and an anode. In some embodiments, the cathode can comprise Li. In some embodiments, the cathode can comprise a material selected from the group consisting of LifePO₄; LiFeₓMn_{y}PO₄, wherein x+y=1; LiMn₂O₄; LiNi_{0.5}Mn_{1.5}O₄; LiNiₓCo_{y}Mn₂O₂, wherein x+y+z=1; LiCoO₂; LiNiₓCo_{y}Al₂O₂, wherein x+y+z=1; and aLiNiₓCo_{y}Mn₂O₂·(1-a)Li₂MnO₃, wherein a is from 0 to 1 and x+y+z=1. In some embodiments, the cathode is Li-free. In some embodiments, the cathode can comprise a material selected from the group of oxides, fluorides, oxyfluorides, sulfur-based materials, and gases. In some embodiments, the cathode can be lithium-containing intercalation chemistry-based or intercalation type-layered (e.g., involving transition metal oxides, transition metal phosphate, vanadium oxides, molybdenum oxides) for Li ion battery or Li metal battery. In some embodiments, the cathode can be sodium-containing intercalation chemistry-based or intercalation-type layered (e.g., involving transition metal oxides, transition metal phosphate, iron hexacyanoferrate (prussian blue, prussian white), vanadium oxides, molybdenum oxides) for Na ion battery or Na metal battery. In some embodiments, the cathode can be potassium-containing intercalation chemistry-based or intercalation type-layered (e.g., involving transition metal oxides, transition metal phosphate, iron hexacyanoferrate (prussian blue, prussian white), vanadium oxides, molybdenum oxides) for K ion battery or K metal battery. In some embodiments, the cathode can comprise a layered lithium intercalated transition metal oxides, lithium intercalated transition metal oxides, lithium intercalated phosphate, pre-lithiated sulfur, pre-lithiated multivalent metal fluorides, pre-lithiated multivalent metal sulfides, or pre-lithiated multivalent metal oxides. In some embodiments, the cathode can comprise a layered sodium intercalated transition metal oxide, sodium intercalated transition metal oxide, sodium intercalated phosphate, sodium intercalated iron hexacyanoferrate (prussian blue, prussian white), pre-sodiated sulfur, pre-sodiated multivalent metal fluorides, pre-sodiated multivalent metal sulfides, or pre-sodiated multivalent metal oxides. In some embodiments, the cathode can comprise a layered potassium intercalated transition metal oxide, potassium intercalated transition metal oxide, potassium intercalated phosphate, potassium intercalated iron hexacyanoferrate (prussian blue, prussian white), pre-potassiated sulfur, pre-potassiated multivalent metal fluorides, pre-potassiated multivalent metal sulfides, or pre-potassiated multivalent metal oxides.

In some embodiments, the anode can be a Li-containing material. In some embodiments, the Li-containing material can be Li metal foil, Li metal on Cu foil, Li metal on carbon substrate, Li metal on porous metal substrate, or Li metal on porous carbon substrate. In some embodiments, the anode comprises an anode material, for example, graphite, graphene, Al, Cu, Si, Sn, SiOₓ, SnOₓ, P, lithium titanium oxide (LTO), hard carbon, soft carbon, or a combination thereof. In some embodiments, the energy device can comprise an electrolyte. In some embodiments, the electrolyte can be a nonaqueous electrolyte, an aqueous electrolyte (e.g., a water-in-salt electrolyte), a semi-solid electrolyte, a liquified gas electrolyte, or a polymer gel electrolyte. The electrolyte material can be a porous material, such that cations or charge carriers can diffuse through the electrolyte. For example, the electrolyte material can be a porous material with an average pore diameter suitable for Li ion diffusion. In some embodiments, the electrolyte salt can be LiPF₆. In some cases, the electrolyte material can be an aqueous electrolyte, such as an ionic liquid. The ionic liquid can be a quaternary amine, such as imidazolium, NH₄⁺, pyrrolidinium, or piperidinium. In some embodiments, a nonaqueous electrolyte may be present. In some embodiments, the nonaqueous electrolyte may comprise a carbonate, an ether, a phosphate, a sulfone, an ionic liquid, an amide, a ketone, an ester, an alcohol, or an aromatic, or combinations thereof. In some embodiments, the carbonate may comprise ethylene carbonate (EC), propylene carbonate (PC), or dimethyl carbonate (DMC), or combinations thereof. In some embodiments, the ether may comprise diethyl ether (DEE), tetrahydrofuran (THF), or dioxolane (DIOX), or combinations thereof. In some embodiments, the phosphate may comprise trimethyl phosphate (TMP), triethyl phosphate (TEP), or combinations thereof. In some embodiments, the sulfone may comprise sulfolane, 1,3-propane sulfone, or combinations thereof. In some embodiments, the ionic liquid may comprise an imidazolium-based salt, or pyridinium-based salt, or combinations thereof. In some embodiments, the amide may comprise N,N-dimethylformamide (DMF), N-methylacetamide (NMA), or combinations thereof. In some embodiments, the ketone may be acetone or 2,3-butanedione. In some embodiments, the ester may be ethyl acetate or butyl acetate. In some embodiments, the alcohol may comprise methanol, ethanol, propanol, isopropanol, or butanol, or combinations thereof. In some embodiments, the nonaqueous electrolyte may comprise an aromatic solvent, such as toluene, xylene, or combinations thereof.

In some embodiments, the energy device can be any type of battery, including, for example, a lithium (Li) battery, a sodium (Na) battery, a potassium (K) battery, a copper (Cu) battery, a zinc (Zn) battery, a magnesium (Mg) battery, or a lithium-ion battery.

### Acoustic Device

In some embodiments, the acoustic device may be coupled with a signal generator. In some embodiments, the signal generator may provide, to the acoustic device, a sinusoidal electrical input signal. In some embodiments, the transducer may be configured to convert this sinusoidal electrical input signal into acoustic waves. In some embodiments, the sinusoidal electrical input signal may create regions of alternating electric polarity within the transducer. These regions of alternating electric polarity may apply tension and compression within and/or upon the substrate. The tension and compression applied within and/or upon the substrate may cause the substrate to oscillate, thereby generating the acoustic waves. In some embodiments, the energy of the acoustic waves may induce acoustic streaming in the electrolyte. Acoustic streaming may be a non-laminar and/or turbulent fluid flow, which may maximize the agitation of the electrolyte and/or the homogenization of the distribution of the cations in the electrolyte. In some embodiments, acoustic streaming may result from the interplay between variations in the density of the electrolyte and variations in the velocity of the electrolyte. The frequency of the acoustic waves, the amplitude of the acoustic waves, and/or the viscosity of the electrolyte may determine whether the acoustic waves are able to induce acoustic streaming in the electrolyte. Acoustic streaming may be achieved at lower frequencies of the acoustic waves, for example, when the viscosity of the electrolyte is between a certain range. For instance, acoustic streaming may be induced in water, which may have a viscosity of 0.890 centipoise at 25° C., when the frequency of the acoustic waves exceeds 1 megahertz (MHz).

In some embodiments, the acoustic waves can comprise at least one of surface acoustic waves (SAW), Lamb waves, flexural waves, thickness mode vibrations, mixed-mode waves, longitudinal waves, love waves, shear mode vibrations, or bulk wave vibrations, or any combination(s) thereof. In some embodiments, the signal generator may provide, to the acoustic device, a square wave electrical input signal.

In some embodiments, the acoustic waves generated by the acoustic device may propagate through an electrolyte filling the interior of the energy device. In some embodiments, the acoustic waves may agitate the electrolyte, thereby homogenizing the distribution of cations in the electrolyte as these cations migrate during the charging of the energy device. Homogenizing the distribution of the cations in the electrolyte may decrease the concentration gradient of the cations in the electrolyte, such that the cations are distributed more evenly throughout the electrolyte. The homogenization of the distribution of the cations may increase the uniformity of the deposits of the cations on at least one of the electrodes.

In some embodiments, the present disclosure provides a system comprising the acoustic device disclosed herein and the energy device. In some embodiments, the energy device can be any energy device provided herein.

### Fabrication Process

In some embodiments, an acoustic device may be fabricated through a lift-off lithography process to deposit a plurality, for example, twenty-eight pairs of un-weighted gold chromium (Au/Cr) fingers to form an optimal interdigital transducer (IDT) onto a 500 mm thick 127.68° Y-rotated, X-propagating cut lithium niobate substrate (LiNbO₃). The acoustic device may be coated with parylene C using chemical vapor deposition to prevent the reactions with the electrolyte present in the energy device. The energy device, as well as the energy device including the integrated acoustic device, may be assembled inside an argon-filled glovebox, where the moisture level and oxygen level are maintained at <1 ppm.

In some embodiments, the present disclosure provides a method of fabricating an acoustic device comprising a transducer. In some embodiments, the method comprises depositing a conductive material onto a surface of a substrate according to a designed pattern. In some embodiments, the method comprises depositing a plurality of finger pairs onto a surface of a substrate according to a designed pattern.

In some embodiments, an acoustic device may be fabricated through a photolithography process to pattern the metal layers onto a piezoelectric substrate. In some embodiments, the acoustic device may be coated with a thin dielectric material, e.g., parylene or SiO₂, to protect the metal layers and prevent electrical shorting.

### Computer Systems

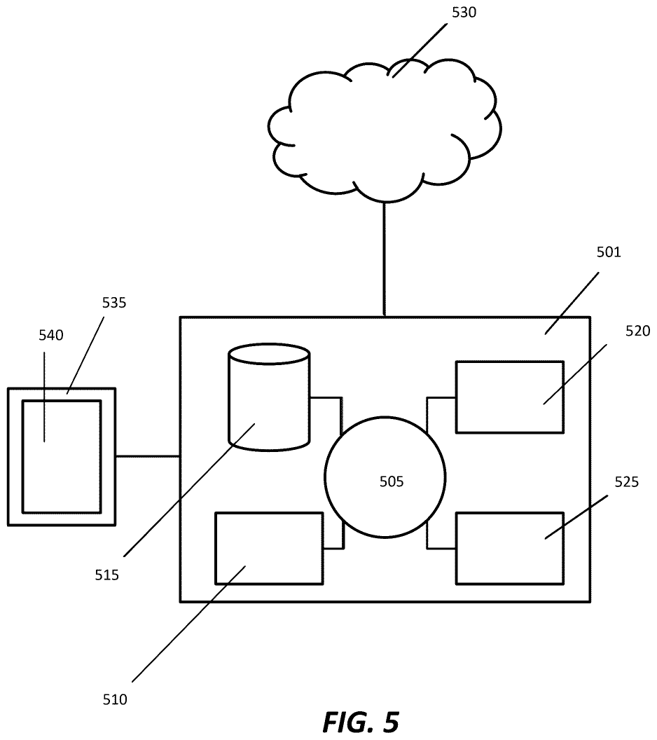

The present disclosure provides computer systems that are programmed to implement methods of the disclosure. FIG. 5 shows a computer system 501 that is programmed or otherwise configured to control an output from a device, system or apparatus according to the embodiments disclosed herein. For example, the computer system 501 may be configured to control an output from an acoustic device or an energy system as described herein. The computer system 501 can regulate various aspects of generating acoustic waves of the present disclosure, such as, for example, frequency, wavelength, amplitude, or power, and types of waveforms. The computer system 501 can be an electronic device of a user or a computer system that is remotely located with respect to the acoustic device or acoustic module according to the disclosure. The electronic device can be a mobile electronic device.

The computer system 501 includes a central processing unit (CPU, also “processor” and “computer processor” herein) 505, which can be a single core or multi-core processor, or a plurality of processors for parallel processing. The computer system 501 also includes memory or memory location 510 (e.g., random-access memory, read-only memory, flash memory), electronic storage unit 515 (e.g., hard disk), communication interface 520 (e.g., network adapter) for communicating with one or more other systems, and peripheral devices 525, such as cache, other memory, data storage, and/or electronic display adapters. The memory 510, storage unit 515, interface 520, and peripheral devices 525 are in communication with the CPU 505 through a communication bus (solid lines), such as a motherboard. The storage unit 515 can be a data storage unit (or data repository) for storing data. The computer system 501 can be operatively coupled to a computer network (“network”) 530 with the aid of the communication interface 520. The network 530 can be the Internet, an intranet, and/or extranet, or an intranet and/or extranet that is in communication with the Internet. The network 530, in some cases, is a telecommunication and/or data network.

The network 530 can include one or more computer servers, which can enable distributed computing, such as cloud computing. The network 530, in some cases with the aid of the computer system 501, can implement a peer-to-peer network, which may enable devices coupled to the computer system 501 to behave as a client or a server.

The CPU 505 can execute a sequence of machine-readable instructions, which can be embodied in a program or software. The instructions may be stored in a memory location, such as the memory 510. The instructions can be directed to the CPU 505, which can subsequently program or otherwise configure the CPU 505 to implement methods of the present disclosure. Examples of operations performed by the CPU 505 can include fetch, decode, execute, and writeback.

The CPU 505 can be part of a circuit, such as an integrated circuit. One or more other components of the system 501 can be included in the circuit. In some cases, the circuit is an application-specific integrated circuit (ASIC).

The storage unit 515 can store files, such as drivers, libraries, and saved programs. The storage unit 515 can store user data, e.g., user preferences and user programs. The computer system 501, in some cases, can include one or more additional data storage units that are external to the computer system 501, such as located on a remote server that is in communication with the computer system 501 through an intranet or the Internet.

The computer system 501 can communicate with one or more remote computer systems through the network 530. For instance, the computer system 501 can communicate with a remote computer system of a user (e.g., a personal health device, laptop, monitoring device, or any other device commonly used by a health practitioner). Examples of remote computer systems include personal computers (e.g., portable PC), slate or tablet PC's (e.g., Apple® iPad, Samsung® Galaxy Tab), telephones, smartphones (e.g., Apple® iPhone, Android-enabled device, Blackberry®), or personal digital assistants. The user can access the computer system 501 via the network 530.

Methods as described herein can be implemented by way of machine (e.g., computer processor) executable code stored on an electronic storage location of the computer system 501, such as, for example, on the memory 510 or electronic storage unit 515. The machine executable or machine-readable code can be provided in the form of software. During use, the code can be executed by the processor 505. In some cases, the code can be retrieved from the storage unit 515 and stored on the memory 510 for ready access by the processor 505. In some situations, the electronic storage unit 515 can be precluded, and machine-executable instructions are stored in memory 510.

The code can be pre-compiled and configured for use with a machine having a processor adapted to execute the code, or can be compiled during runtime. The code can be supplied in a programming language that can be selected to enable the code to execute in a pre-compiled or as-compiled fashion.

Aspects of the systems and methods provided herein, such as the computer system 501, can be embodied in programming. Various aspects of the technology may be thought of as “products” or “articles of manufacture,” typically in the form of machine (or processor) executable code and/or associated data that is carried on or embodied in a type of machine-readable medium.

Machine-executable code can be stored on an electronic storage unit, such as memory (e.g., read-only memory, random-access memory, flash memory) or a hard disk. “Storage” type media can include any or all of the tangible memory of the computers, processors, or the like, or associated modules thereof, such as various semiconductor memories, tape drives, disk drives, and the like, which may provide non-transitory storage at any time for the software programming. All or portions of the software may at times be communicated through the Internet or various other telecommunication networks. Such communications, for example, may enable loading of the software from one computer or processor into another, for example, from a management server or host computer into the computer platform of an application server. Thus, another type of media that may bear the software elements includes optical, electrical, and electromagnetic waves, such as those used across physical interfaces between local devices, through wired and optical landline networks, and over various air-links. The physical elements that carry such waves, such as wired or wireless links, optical links, or the like, may also be considered as media bearing the software. As used herein, unless restricted to non-transitory, tangible “storage” media, terms such as computer or machine “readable medium” refer to any medium that participates in providing instructions to a processor for execution.

Hence, a machine-readable medium, such as computer-executable code, may take many forms, including but not limited to a tangible storage medium, a carrier wave medium, or a physical transmission medium. Non-volatile storage media include, for example, optical or magnetic disks, such as any of the storage devices in any computer(s) or the like, such as may be used to implement the databases, etc., shown in the drawings. Volatile storage media include dynamic memory, such as the main memory of a computer platform. Tangible transmission media include coaxial cables, copper wire, and fiber optics, including the wires that comprise a bus within a computer system. Carrier-wave transmission media may take the form of electric or electromagnetic signals, or acoustic or light waves such as those generated during radio frequency (RF) and infrared (IR) data communications. Common forms of computer-readable media therefore include for example: a floppy disk, a flexible disk, hard disk, magnetic tape, any other magnetic medium, a CD-ROM, DVD or DVD-ROM, any other optical medium, punch cards paper tape, any other physical storage medium with patterns of holes, a RAM, a ROM, a PROM and EPROM, a FLASH-EPROM, any other memory chip or cartridge, a carrier wave transporting data or instructions, cables or links transporting such a carrier wave, or any other medium from which a computer may read programming code and/or data. Many of these forms of computer-readable media may be involved in carrying one or more sequences of one or more instructions to a processor for execution.

The computer system 501 can include or be in communication with an electronic display 535 that comprises a user interface (UI) 540 for providing. Examples of UI's include, without limitation, a graphical user interface (GUI) and a web-based user interface.

Methods and systems of the present disclosure can be implemented by way of one or more algorithms. An algorithm can be implemented by way of software upon execution by the central processing unit 505.

### EXAMPLES

The following examples are provided to further illustrate some embodiments of the present disclosure, but are not intended to limit the scope of the disclosure; it will be understood by their exemplary nature that other procedures, methodologies, or techniques known to those skilled in the art may alternatively be used.

### Example 1: Performance of Transducers

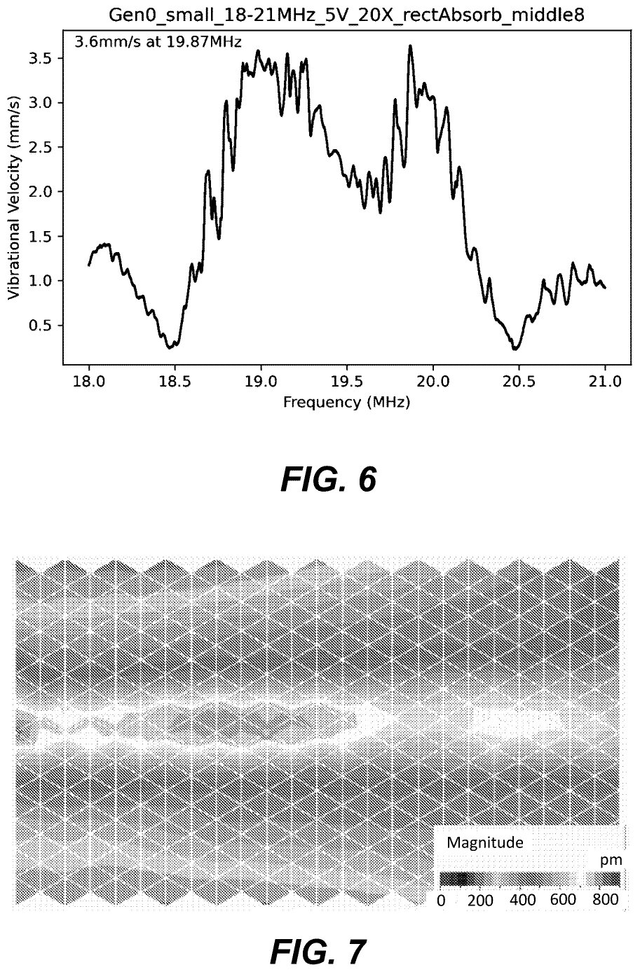

The performances of exemplary SIDT, FIDT, and TMT transducers were measured with a laser Doppler vibrometer (LDV). The dimensions of the transducers are shown in Table 1. The LDV calculates the Doppler shift between a reference laser beam, which does not interact with the vibrating face of the sample, and a measurement laser beam, which interacts with the vibrating face of the sample. The measurement was performed while supplying a voltage signal with a particular frequency to the transducer. A set of measurements was taken over a range of signal frequencies and at a range of locations on the surface. The measurement yields the vibrational velocity (VV) of the surface in the direction normal to the surface. The result is a spectrum of vibrational velocity amplitudes for each location, which can be averaged over all locations. FIG. 6 shows an example VV spectrum (VV vs frequency (MHz) of SIDT1.0 of Table 1. The VV is an average over multiple spatial points of a multi-frequency measurement.

The VV spectrum can be used to determine the optimal frequency of the voltage signal supplied to the transducer. Once an optimal frequency has been chosen, the measurement was repeated without varying the signal frequency. Table 1 shows the Peak VV, which is the largest vibrational velocity amplitude, and the Avg VV, which is the average of the VV of all locations on the surface measured. The voltage signal was 5V, and the measurements were taken at a 0.5 by 0.5 mm range of locations on the surface.

TABLE 1
Transducer performance and parameters

| | | F_{w} | Fₛ | A | | R_{w} | Rₛ | Peak VV | Avg VV |
|---|---|---|---|---|---|---|---|---|---|
| Design | N_{fp} | (μm) | (μm) | (mm) | Nᵣ | (μm) | (μm) | (mm/s) | (mm/s) |
| SIDT1.0 | 40 | 50 | 50 | 4.7 | 0 | N/A | N/A | 270 | 176 |
| SIDT1.1 | 30 | 50 | 50 | 6 | 16 | 50 | 50 | 285 | 185 |
| SIDT1.3 | 30 | 50 | 50 | 6 | 0 | N/A | N/A | 260 | 169 |
| SIDT1.5 | 10 | 50 | 50 | 6 | 8 | 50 | 50 | 413 | 268 |
| SIDT1.6 | 20 | 50 | 50 | 6 | 8 | 50 | 50 | 391 | 254 |
| SIDT1.7 | 20 | 50 | 50 | 8 | 8 | 50 | 50 | 385 | 250 |
| SIDT1.8 | 20 | 44.4 | 44.4 | 6 | 8 | 44.4 | 44.4 | 322 | 209 |
| SIDT1.12 | 20 | 66.7 | 66.7 | 6 | 0 | N/A | N/A | 372 | 242 |
| SDIT1.13 | 20 | 100 | 100 | 6 | 0 | N/A | N/A | 359 | 233 |
| | | F_{w} | Fₛ | D | L_{f} | | | | |
| | N_{fp} | (μm) | (μm) | (deg) | (mm) | Nᵣ | | | |
| FIDT1 | 30 | 28.6 | 28.6 | 70 | 5.7 | 16 | | 890 | 200 |
| | L | W | T | | | | | | |
| | (mm) | (mm) | (mm) | | | | | | |
| TMT1 | 6 | 6 | 0.5 | | | | | 694 | 337 |

FIDT1 produced the largest Peak VV, the Avg VV was relatively low, and the location where the Peak VV occurred was relatively far away from the IDT structure, thus requiring the transducer to be larger in lateral extent. TMT1 produced both large Peak VV and large Avg VV. In some cases, TMT1 may not isolate vibration to the surface of the transducer.

For SIDTs, the effect of the number of reflectors on vibrational velocity was relatively small for SIDTs tested in this example. Relatively high Peak VV and Avg VV can be produced at a wide range of numbers of finger pairs and finger widths. In some cases, if a small lateral footprint of the transducer is desirable, fewer reflectors and finger pairs can be used. In some cases, the signal frequency of the SIDTs can be shifted to match the energy devices with which it is paired.

FIG. 7 shows an example spatial map of the surface of an FIDT device near the focal spot. FIG. 7 shows that acoustic energy is being focused from right to left for the FIDT device. For a given horizontal line, the magnitude increases from right to left. The gradient in magnitude for a vertical line on the left of the map is significantly larger than for a vertical line on the right. For an SIDT, the gradient would be equal regardless of the location of the vertical line. This leads directly to the observation in Table 1 that the FIDT generally had a larger peak vibrational velocity than SIDT, even though its average vibrational velocity was comparable.

This example demonstrates that different transducers can be selected and customized to meet different needs in the characteristics of the acoustic waves.

While preferred embodiments of the present disclosure have been shown and described herein, such embodiments are provided by way of example only. Numerous variations, changes, and substitutions will now occur without departing from the disclosure. It should be understood that various alternatives to the embodiments of the present disclosure may be employed in practicing the present disclosure. It is intended that the following claims define the scope of the present disclosure and that methods and structures within the scope of these claims and their equivalents be covered thereby.

1. A system, comprising:
an energy device, comprising an electrochemical cell having a cell surface; and
an acoustic device operably coupled to the energy device, wherein:
the acoustic device has a size that is substantially same or smaller than a size of a cell of the energy device,
the acoustic device comprises a substrate and one or more transducers patterned onto the substrate, and
the one or more transducers comprise at least one of:
(a) an FIDT-W comprising a plurality of fingers in a shape of a slowness curve of the substrate,
(b) a thickness mode transducer (TMT) comprising a top electrode and a bottom electrode deposited onto a top surface and a bottom surface of the substrate, respectively, or
(c) a lamb wave transducer (LWT) comprising a combined IDT and bottom electrode, the combined IDT comprising a plurality of fingers and a plurality of reflectors deposited on the top surface of the substrate, and the bottom electrode deposited on the bottom surface of the substrate.

2. The system of claim 1, wherein:
the one or more transducers comprise the FIDT-W, and
the FIDT-W comprises a pair of electrode busbars and a plurality of reflectors.

3. The system of claim 2, wherein:
one or more physical or geometric design parameters for the FIDT-W comprise one or more of: number of finger pairs (Nfp), finger width (Fw), spacing between fingers (Fs), focal angle (D), focal length (Lf), number of reflectors (Nr), reflector width (Rw), spacing between reflectors (Rs), space between last finger and first reflector (FRs), width of electrode busbar (B), length of electrode busbar (L), or curvature of the fingers, and
wherein Nfp is 5 to 50, Fw is 5 μm to 100 μm, Fs is 5 μm to 100 μm, D is 30 degrees to 90 degrees, Lf is 2 mm to 20 mm, Nr is 0 to 50, Rw is 5 μm to 100 μm, Rs is 5 μm to 100 μm, FRs is 5 μm to 300 μm, B is 0.5 mm to 50 mm, or L is 0.5 mm to 50 mm.

4. The system of claim 2, wherein the plurality of fingers has a curvature in a center of the FIDT-W that is at least 20% larger than a curvature at an edge of the FIDT-W.

5. The system of claim 2, wherein an axis of the FIDT-W is parallel to a direction of propagation of sound or acoustic wave in the substrate.

6. The system of claim 1, wherein:
the one or more transducers further comprise a circular arc FIDT (FIDT-C),
the FIDT-C comprises a plurality of fingers in a shape of concentric circles, and
the FIDT-C comprises a plurality of reflectors disposed on a side of the FIDT-C opposite a focal spot.

7. The system of claim 1, wherein the one or more transducers comprise the TMT.

8. The system of claim 7, wherein:
the TMT has a rectangular shape with one or more geometric design parameters comprising a length (L), a width (W), and a thickness (T), and
the length (L) is 1-50 mm, the width (W) is 1-50 mm, and the thickness (T) is 0.2-2 mm.

9. The system of claim 7, wherein:
the TMT has an elliptical shape with one or more geometric design parameters comprising a first radius (R1), a second radius (R2), and a thickness (T), and
the first radius (R1) is 0.5-25 mm, the second radius (R2) is 0.5-25 mm, and a thickness (T) is 0.2-2 mm.

10. The system of claim 1, wherein:
the one or more transducers comprise the LWT, and
the combined IDT comprises a straight finger interdigital transducer (SIDT) or a focused interdigital transducer (FIDT).

11. The system of claim 10, wherein:
one or more physical or geometric design parameters for the LWT comprise one or more of: number of finger pairs (Nfp), finger width (Fw), spacing between fingers (Fs), aperture width (A), number of reflectors (Nr), reflector width (Rw), spacing between reflectors (Rs), space between last finger and first reflector (FRs), width of electrode busbar (B), length of electrode busbar (L), length of electrode busbar extension to left (Lext1), or length of electrode busbar extension to right (Lext2), and
Nfp is 5 to 50, Fw is 5 μm to 100 μm, Fs is 5 μm to 100 μm, A is 2 mm to 20 mm, Nr is 0 to 50, Rw is 5 μm to 100 μm, Rs is 5 μm to 100 μm, FRs is 5 μm to 300 μm, or B is 0.5 mm to 50 mm.

12. The system of claim 1, wherein the one or more transducers comprise at least two different types of transducers selected from the group consisting of the FIDT-W, the TMT, and the LWT.

13. The system of claim 1, wherein the substrate has a thickness of 250-1000 micrometers.

14. The system of claim 1, wherein the substrate comprises a lithium niobate single crystal grown on a carrier.

15. The system of claim 14, wherein the carrier comprises sapphire.

16. The system of claim 1, wherein the one or more transducers comprise a conductive material comprising titanium, aluminum, copper, chromium, gold, nickel, tungsten, tin, or a combination thereof.

17. The system of claim 16, wherein the conductive material comprises a combination of tungsten and titanium.

18. The system of claim 1, wherein the acoustic device is disposed at an exterior of the energy device.

19. The system of claim 1, wherein the acoustic device is disposed at various locations on an interior of the energy device.

20. The system of claim 1, wherein the energy device comprises a solid-state battery, a semi-solid-state battery, a fuel cell, an electrolyzer, a flow battery, or a metal-air battery.
